(19) United States
(12) Patent Application Publication
(10) Pub. No.: US 2009/0267118 A1
(43) Pub. Date: Oct. 29, 2009

(54) METHOD FOR FORMING CARBON SILICON ALLOY (CSA) AND STRUCTURES THEREOF

(75) Inventors: Ashima B. Chakravarti, Hopewell Junction, NY (US); Abhishek Dube, Fishkill, NY (US); Rainer Loesing, Newburgh, NY (US); Dominic J. Schepis, Wappingers Falls, NY (US)

Correspondence Address: HOFFMAN WARNICK LLC, 75 STATE ST, 14TH FL, ALBANY, NY, 12207, US

(73) Assignee: INTERNATIONAL BUSINESS MACHINES CORPORATION, Armonk, NY (US)

(21) Appl. No.: 12/111,377

(22) Filed: Apr. 29, 2008

(51) Int. Cl. H01L 49/00; H01L 21/20

(52) U.S. Cl. 257/288; 438/508; 257/E49.001; 257/E21.09

(57) ABSTRACT

Methods for forming carbon silicon alloy (CSA) and structures thereof are disclosed. The method provides improvement in substitutionality and deposition rate of carbon in epitaxially grown carbon silicon alloy layers (i.e., substituted carbon in Si lattice). In one embodiment of the disclosed method, a carbon silicon alloy layer is epitaxially grown on a substrate at an intermediate temperature with a silicon precursor, a carbon (C) precursor in the presence of an etchant and a trace amount of germanium material (e.g., germane (GeH₄)). The intermediate temperature increases the percentage of substitutional carbon in epitaxially grown CSA layer and avoids any tendency for silicon carbide to form. The presence of the trace amount of germanium material, of approximately less than 1% to approximately 5%, in the resulting epitaxial layer, has an effect of stabilizing and enhancing deposition/growth rate without compromising the tensile stress of CSA layer formed thereby.

### BACKGROUND

1. Technical Field

The disclosure relates generally to formation of carbon silicon alloy (CSA) epitaxial layers during fabrication of N-doped field effect transistors (nFET), and more particularly, to methods of forming CSA epitaxial layers with high degree of substitutional carbon at accelerated growth rates.

2. Background Art

In the current state of the art, epitaxial growth of carbon silicon alloy (CSA) on a silicon substrate is accomplished by chemical vapor deposition (CVD) using a mixture of precursors and etchants in a carrier gas. The carbon is added to generate tensile stress in epitaxially grown CSA layers in order to improve the performance of n-doped field effect transistor (nFET) fabricated therefrom.

However, epitaxial growth of CSA layers is very complicated for a number of reasons. For example, the growth of epitaxial layers is heavily dependent on the substrate surface on which the epitaxial layer is grown (i.e., the crystalline properties of the substrate as well as a pristine surface having low interfacial oxygen and carbon has an influence on the growth of CSA layer thereon). Therefore, the starting substrate plays an important part in the epitaxial growth.

Another challenge in the epitaxial growth of CSA layers may include the low solid solubility of carbon (C) in a Si lattice. In the event where equilibrium conditions prevail (i.e. at high temperatures) the carbon may be incorporated in high amounts leading to formation of silicon carbide (SiC) layers instead of carbon silicon alloy layers (i.e., where substitutional carbon resides in the lattice of the Si layer). The tendency for formation of silicon carbide is attributed to a high thermodynamic stability which promotes the tendency for SiC precipitation over low amounts (at approximately 1%-2%) of C substitution in epitaxially grown Si lattice.

One way to circumvent the formation of SiC is to conduct the deposition at a lower temperature and at a high deposition rate. Typically, this is achieved using Si precursors that decompose at a lower temperature than silane (SiH₄). An example of such a precursor is Si₃H₈ (Silicore™, which is a trademark of Jordan Industries, Inc. in the United States and/or other countries). However, the low temperature may compromise the effectiveness of a typical etchant (e.g., hydrogen chloride (HCl)) for promoting selective epitaxial growth of CSA. This result limits the use of such epitaxial chemistries of Si precursors and etchants for selective deposition of CSA.

### SUMMARY

Methods for forming carbon silicon alloy (CSA) and structures thereof are disclosed. The method provides improvement in substitutionality and deposition rate of carbon in epitaxially grown carbon silicon alloy layers (i.e., substituted carbon in Si lattice). In one embodiment of the disclosed method, a carbon silicon alloy layer is epitaxially grown on a substrate at an intermediate temperature with a silicon precursor, a carbon (C) precursor in the presence of an etchant and a trace amount of germanium material (e.g., germane (GeH₄)). The intermediate temperature increases the percentage of substitutional carbon in epitaxially grown CSA layer and avoids any tendency for silicon carbide to form. The presence of the trace amount of germanium material, of approximately less than 1% to approximately 5%, in the resulting epitaxial layer, has an effect of stabilizing and enhancing deposition/growth rate without compromising the tensile stress of CSA layer formed thereby.

A first aspect of the disclosure provides a method for forming a carbon silicon alloy (CSA) layer on a substrate, the method comprising: depositing a carbon silicon alloy layer on a silicon portion of the substrate, the depositing including mixing a silicon (Si) precursor, a carbon (C) precursor and a germanium material (Ge) in a carrier gas; and etching any carbon silicon alloy material formed on any non-silicon portion of the substrate with an etchant.

A second aspect of the disclosure provides a semiconductor structure comprising: a carbon silicon alloy layer disposed on a substrate, the carbon silicon alloy layer including: substitutional carbon (C) incorporated in a silicon (Si) lattice; and approximately less than 1% to approximately 5% of germanium (Ge) therein.

A third aspect of the disclosure provides a semiconductor structure comprising: a gate disposed on a substrate, the substrate including a source-drain region below the gate, wherein the source-drain region includes a carbon silicon alloy (CSA) layer with approximately less than 1% to approximately 5% germanium (Ge) incorporated therein.

These and other features of the present disclosure are designed to solve the problems herein described and/or other problems not discussed.

### BRIEF DESCRIPTION OF THE DRAWINGS

Various aspects of the disclosure will be more readily understood from the following detailed description taken in conjunction with the accompanying drawings that depict different embodiments of the disclosure, in which:

FIG. 1 is a flow diagram of an embodiment of the processes of the disclosure.

FIG. 2 is a cross-sectional view of an embodiment of a structure of an nFET during the fabrication process of the disclosed method.

FIG. 3 is a cross-sectional view of the embodiment of the structure of an nFET from FIG. 2.

FIG. 4A is a graph illustrating the number of carbon, oxygen and silicon atoms per unit volume in a carbon silicon alloy film formed using prior art methods.

FIG. 4B is a graph illustrating the number of carbon, germanium, oxygen and silicon atoms per unit volume in a carbon silicon layer formed using the disclosed method in FIG. 1.

FIG. 5A is a graph illustrating number of carbon, germanium, oxygen and silicon atoms per unit volume in a carbon silicon layer formed using prior art methods.

FIG. 5B is a graph illustrating number of carbon, germanium, oxygen and silicon atoms per unit volume in a carbon silicon layer formed using the disclosed method in FIG. 1.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

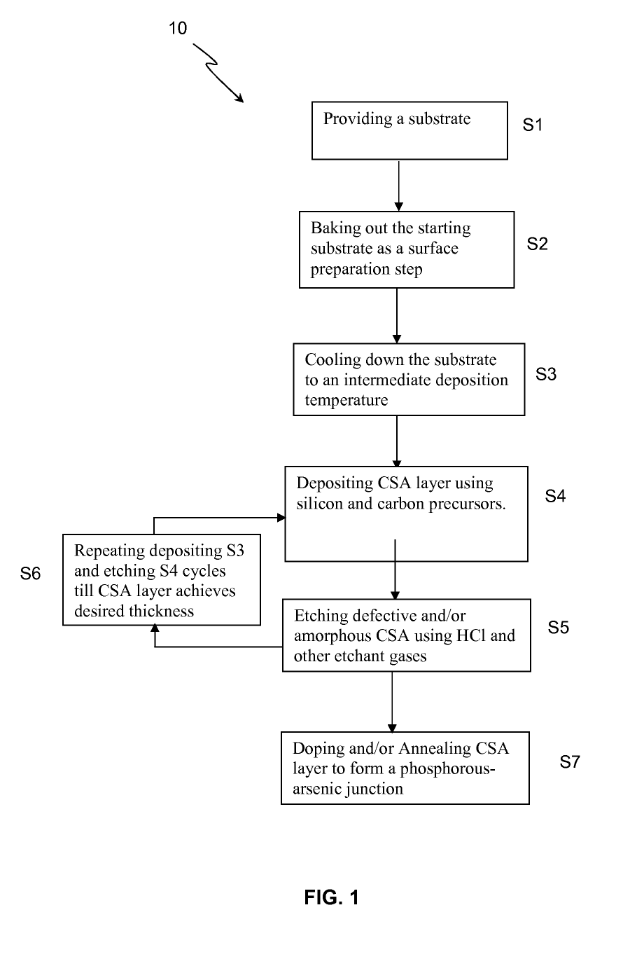

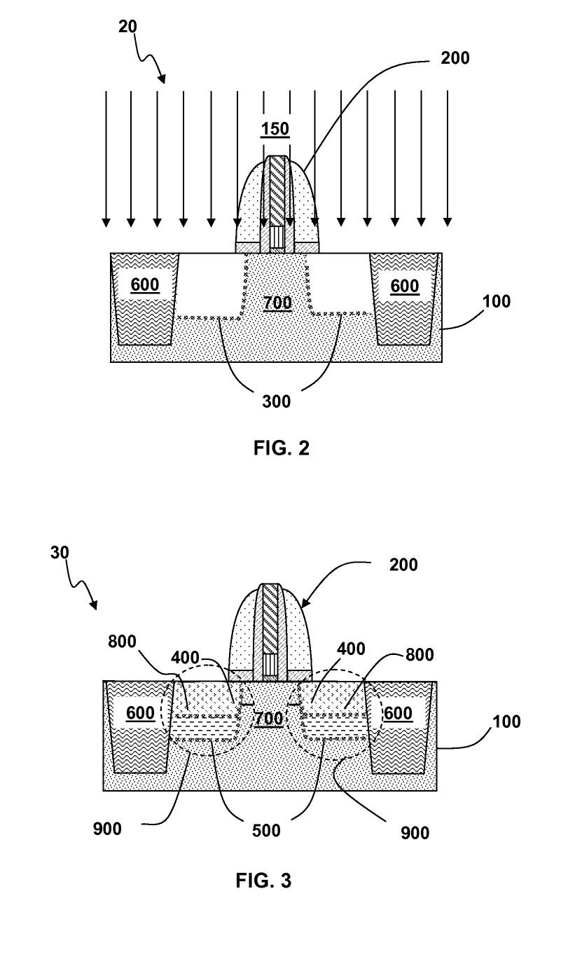

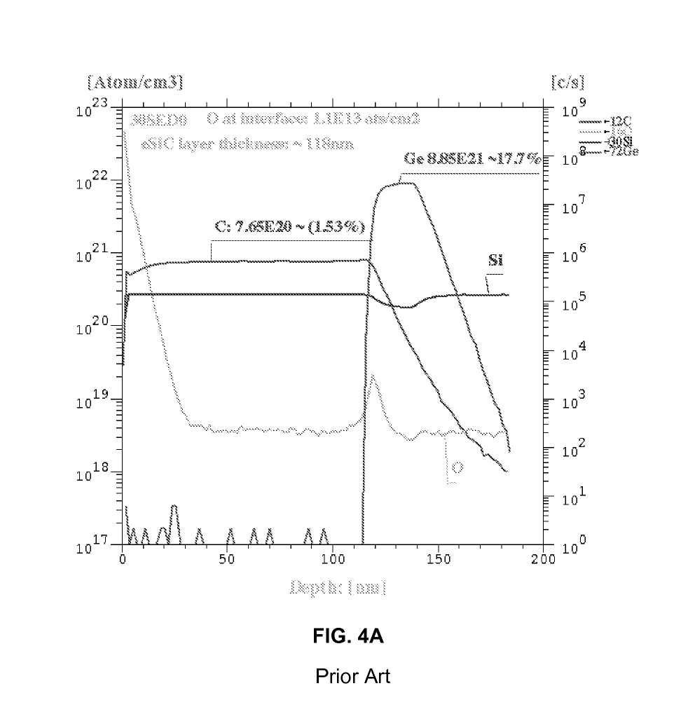

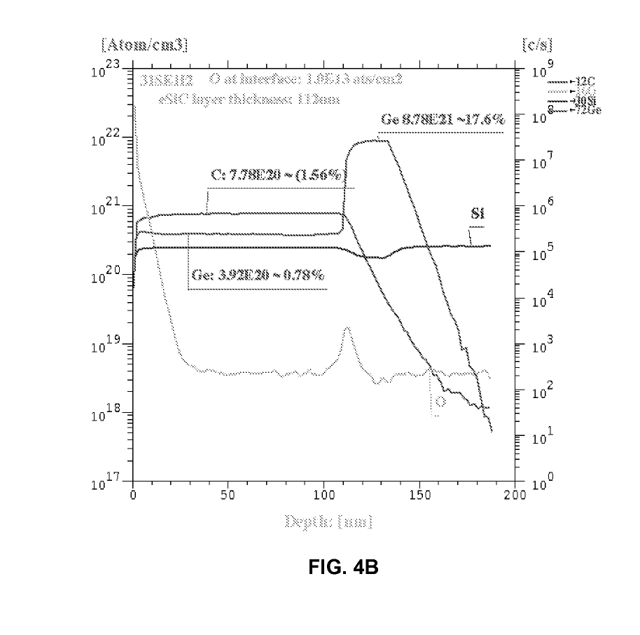

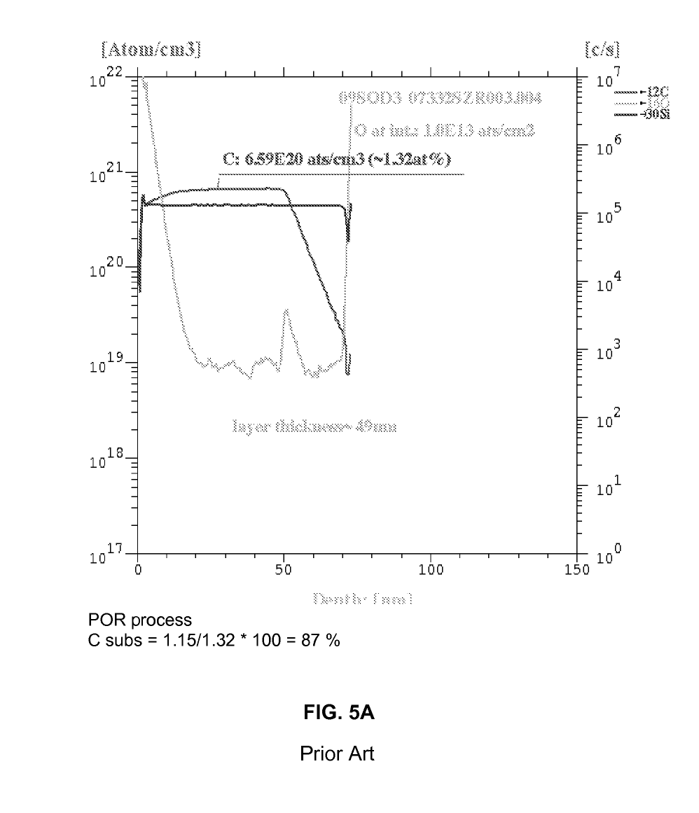

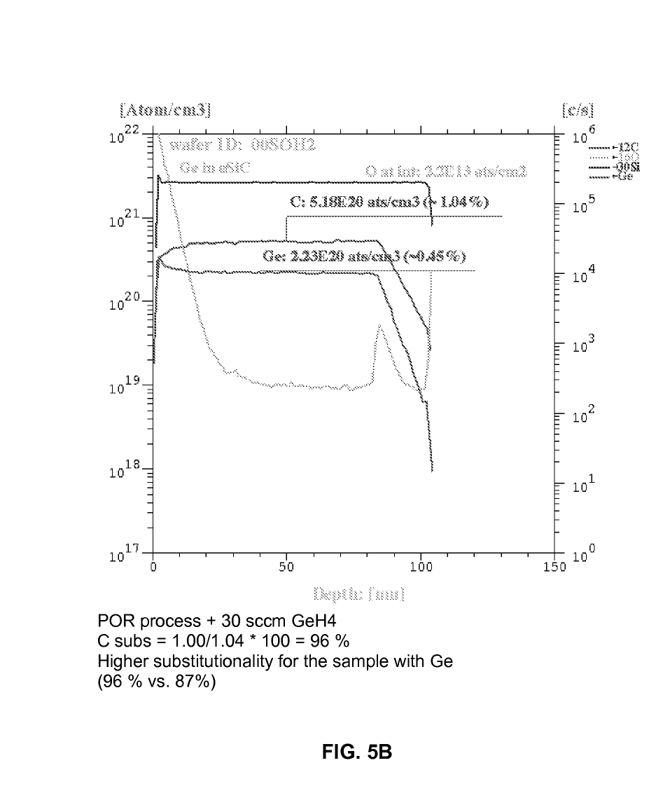

Embodiments depicted in the drawings in FIG. 1-3 illustrate the methods and various resulting structure(s) of the different aspects of fabricating an nFET 30 (FIG. 3) in a CMOS using epitaxial layers of CSA disposed on a substrate 100 (FIGS. 2 and 3). Examples of tests results of performance of structures formed by the disclosed method are illustrated in FIGS. 4A-5A.

FIG. 1 illustrates a flow diagram of a process including processes S1-S7 of an embodiment of the disclosed method. A CMOS semiconductor structure 20 as shown in FIG. 2 is provided in process S1. Semiconductor structure 20 is fabricated according to currently known or later developed techniques. The structure 20 may include a gate 200 disposed on a substrate 100. Substrate 100 may include silicon sites, for example, recesses 300 shown in FIG. 2 and non-silicon sites, for example, shallow trench isolation (STI) 600, incorporated therein. Recesses 300 are formed using currently known or later developed etching techniques, for example reactive ion etching (RIE). The substrate 100 may also include silicon-on-insulator (SOI) (not shown) or bulk silicon. Epitaxial growth 150 according to process S1-S6 fills recesses 300 forming CSA source/drain regions 500 (FIG. 3).

According to process S2 (FIG. 1) of the disclosed method, substrate 100 is subject to a currently known or later developed bake-out process (i.e., annealing in the presence of hydrogen) for preparing the surface of the substrate for epitaxial growth thereon.

Substrate 100 (FIG. 2) is then cooled to an intermediate deposition temperature according to process S3 by a currently known or later developed technique. The intermediate deposition temperature for the epitaxial growth of a carbon silicon alloy (CSA) 500 (FIG. 3) layer is maintained at approximately 550° C. to approximately 700° C., preferably at approximately 600° C. to approximately 650° C. At this intermediate deposition temperature, the tendency for carbon to form silicon carbide is avoided while substitutional carbon in the silicon lattice is increased to form carbon silicon alloy (CSA).

Maintaining the intermediate deposition temperature, a mixture including a silicon (Si) precursor, a carbon (C) precursor, and an etchant in a carrier gas may be introduced in a quartz reactor chamber (not shown) for epitaxial growth according to process S4. Currently known or later developed techniques, for example, chemical vapor deposition (CVD) may be applied to achieve the epitaxial growth. The Si precursor may include, for example, but not limited to: silicon tetrachloride (SiCl₄); trichlorosilane (SiHCl₃); dichlorosilane (SiH₂Cl₂); silane (SiH₄); disilane (Si2H6); or other higher order silanes. The C precursor may include organo silane materials, for example, but not limited to: mono-methyl silane and ethylene; and other higher order organo silanes. A typical carrier gas may include, for example, but not limited to helium (He), hydrogen (H₂), nitrogen (N₂), and other noble gases. A trace amount of germanium in the form germanium materials/compounds may be introduced into the mixture. For example, an amount of germane (GH₄), of approximately 0.02% by volume to approximately 0.05% by volume, maybe added in the mixture following dilution in a carrier gas. The reactants may have a proportional relationship where silicon (Si) precursor: carbon (C) precursor: germane (GeH₄) is 5000:100:1.

The mixture in process S4 may include an amount of organo germanium, for example, methylgermane (MeGeH₃) and other organically substituted germanes, for increasing the substitutionality and deposition rate of substitutional carbon in the formation of the CSA layer 500 (FIG. 3) on the substrate 100 (FIG. 3) during epitaxial growth. The amount of organo germanium is then mixed with the Si and C precursors in the carrier gas. The following examples in FIGS. 4A-5B illustrate test results from samples of CSA formed by the disclosed method in comparison with those formed by prior art methods.

FIG. 4A illustrates a graph showing the respective number of atoms of carbon (C), germanium (Ge), oxygen (O) and silicon (Si) per unit volume in a sample CSA layer grown on a silicon-germanium substrate where epitaxial growth is performed in the absence of germanium. The resultant structure (not shown) provides an interface between the substrate surface and the CSA layer where the percentage of oxygen is approximately 1.1×10¹³ atoms/cm². FIG. 4B illustrates a graph showing the respective number of atoms of carbon (C), germanium (Ge), oxygen (O) and silicon (Si) per unit volume in a CSA layer grown on a silicon germanium nucleation layer on a silicon substrate where germanium is introduced in CSA epitaxial growth process S4 according to the disclosed method. Germanium may be introduced at approximately 0.1 standard cubic centimeters per minute (sccm) into the mixture of reactants. In this sample, the percentage of oxygen at the interface between the substrate surface and the CSA layer is approximately 1.0×10¹³ atoms/cm². Comparing the results between the two samples, there is approximately 10% less oxygen at the interface between the substrate and the CSA layer in the sample where epitaxial growth was conducted in the presence of germanium. This is attributed to the catalytic effect of germanium (Ge) in the epitaxial growth process S4. Germanium has a tendency to actively remove any oxygen contamination at the surface of the substrate improving interface quality. With improved interface quality, the deposition rate of CSA layer may be increased.

In addition to improving deposition rate, the catalytic effect of germanium (Ge) also provides for epitaxial growth of a CSA layer at a lower deposition temperature range. This promotes the incorporation of substitutional carbon in the silicon (Si) lattice leading to increased substituted carbon (C) in epitaxially grown CSA layer.

FIG. 5A illustrates a graph showing the respective number of carbon (C), oxygen (O) and silicon (Si) atoms per units volume in a CSA layer grown on a silicon substrate where epitaxial growth is performed in the absence of germanium. From FIG. 5A, the depth of the CSA layer in a sample (not shown) is approximately 49 nm with a percentage of substituted carbon at approximately 87%. FIG. 5B illustrates a graph showing the respective number of carbon (C), germanium (Ge), oxygen (O) and silicon (Si) per unit volume in a CSA layer 500 (FIG. 3) grown on silicon substrate 100 (FIG. 3) where germanium is introduced during epitaxial growth process S4. From FIG. 5B, the percentage of substitutional carbon in CSA layer 500 (FIG. 3) may be as high as approximately 96% with the depth of CSA layer 500 reaching approximately 100 nm. By introducing trace amount of approximately 2.23×10²⁰ atoms/cm³ (i.e., approximately 0.45%) of germane, the percentage of substituted C in the Si lattice is increased by approximately 10%.

In process S5, CSA layer 500, as shown in FIG. 3, is etched to remove any growth on non-silicon sites 600 on the substrate 100. The etchant may include, for example, but not limited to chlorine, hydrogen chloride or a combination thereof.

Process S6 is a cyclic-deposition and etch (CDE) process where the deposition process S3 and etching process S4 are repeated until the desired thickness of the CSA layer 500, shown in FIG. 3, is achieved. The desired thickness of the CSA layer depends on the feature/structure to be formed. With germanium included in process S4, S5 and S6, the resultant CSA layer usually presents an increased in the percentage of substitutional carbon in the Si lattice of the CSA layer. With an increase in substitutional carbon in the Si lattice, epitaxial growth of the CSA layer 500 (FIG. 3) as an epitaxial fill for forming source-drain regions 900 (FIG. 3) in the semiconductor structure 30 (FIG. 2) may achieve the same effect as a film having lower percentage of substitutional carbon with no dislocations therein. CSA 500 for filling recess 300 (FIG. 2) to form source-drain regions 900 presents a continuous layer without any crystalline dislocations therein.

With each cycle depositing an increased of substitutional C, the number of cycles in the CDE process S6 for epitaxial growth of CSA layer 500 as an epitaxial fill in the recesses 300 to form source-drain regions 500 (FIG. 3) is reduced. With the reduction of the number of cycles, the time for forming source-drain regions 900 is reduced.

With process S7, the newly formed CSA layer 500, as shown in FIG. 3 may be doped with phosphorous (P) and arsenic (As) to form a junction 800 therebetween. The presence of approximately 1% to approximately 5% of germanium in CSA layer 500 improves dopant control through phosphorous and arsenic junction engineering. Dopant activation is increased while diffusion of dopant is maintained at a minimum in the presence of Ge. The addition of Ge can eliminate/lower the temperature range and duration required for the dopant activation anneal.

According to the disclosed method, the resultant nFET structure 30 has a tensile strain 400 in channel 700 (FIGS. 2 and 3) that is formed between the source/drain region 900. The CSA layer 500 in source-drain regions 900 creates the tensile strain 400 which is not compromised because of the intermediate deposition temperature used for the epitaxial growth.

The foregoing description of various aspects of the disclosure has been presented for purposes of illustration and description. It is not intended to be exhaustive or to limit the scope of the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A method for forming a carbon silicon alloy (CSA) layer on a substrate, the method comprising:
depositing a carbon silicon alloy layer on a silicon portion of the substrate, the depositing including mixing a silicon (Si) precursor, a carbon (C) precursor and a germanium material (Ge) in a carrier gas; and
etching any carbon silicon alloy material formed on any non-silicon portion of the substrate with an etchant.

2. The method according to claim 1, wherein the Si precursor, C precursor and germanium material (Ge) includes a proportional relationship of 5000(Si):100(C):1(Ge).

3. The method according to claim 1, wherein the germanium material includes germane or methylgermane (MeGeH₃).

4. The method according to claim 3, wherein the germanium material ranges from approximately 0.02% by volume to approximately 0.05% by volume.

5. The method according to claim 1, further comprising annealing the substrate in the presence of hydrogen before the depositing.

6. The method according to claim 5, further comprising cooling the substrate to a temperature ranging from approximately 550° C. to approximately 700° C.

7. The method according to claim 6, further comprising cooling the substrate to a temperature ranging from approximately 600° C. to approximately 650° C.

8. The method according to claim 1, wherein the silicon precursor includes silicon tetrachloride (SiCl₄), trichlorosilane (SiHCl₃), dichlorosilane (SiH₂Cl₂), silane (SiH₄), or disilane (Si₂H6).

9. The method according to claim 1, wherein the carbon (C) precursor is an organo silane material including methyl silane and ethylene.

10. The method according to claim 1, wherein the etchant includes chlorine and hydrogen chloride.

11. The method according to claim 1, further comprising repeating the depositing and the etching.

12. The method according to claim 1, furthering comprising doping the carbon silicon alloy layer with arsenic and phosphorous to form a phosphorous arsenic junction therein.

13. A semiconductor structure comprising:
a carbon silicon alloy layer disposed on a substrate, the carbon silicon alloy layer including: substitutional carbon (C) incorporated in a silicon (Si) lattice; and approximately less than 1% to approximately 5% of germanium (Ge) therein.

14. The structure of claim 13, wherein the carbon silicon alloy is an epitaxial fill in a recess in a silicon portion of the substrate, the carbon silicon alloy has a proportional relationship of 5000(Si):100(C):1(Ge).

15. The structure of claim 14, wherein the epitaxial fill in the recess forms a source-drain region for a gate conductor.

16. The structure of claim 13, wherein the carbon silicon alloy layer is a continuous layer free of crystalline dislocations.

17. The structure of claim 16, wherein the carbon silicon alloy further includes a phosphorous-arsenic junction.

18. A semiconductor structure comprising:
a gate disposed on a substrate, the substrate including a source-drain region below the gate, wherein the source-drain region includes a carbon silicon alloy (CSA) layer with approximately less than 1% to approximately 5% germanium (Ge) incorporated therein.

19. The structure of claim 18, wherein the carbon silicon alloy includes a proportional relationship of 5000(Si):100(C):1 (Ge).

20. The structure of claim 19, wherein the carbon silicon alloy layer includes a phosphorous-arsenic junction therein.
